(19) United States
(12) Patent Application Publication
(10) Pub. No.: US 2013/0284710 A1
(43) Pub. Date: Oct. 31, 2013

(54) Method and Apparatus for the Line Narrowing of Diode Lasers

(71) Applicant: TransLith Systems, LLC, (US)

(72) Inventors: Paul Hoff, Bedford, NH (US); Donald Ronning, Nashua, NH (US)

(21) Appl. No.: 13/855,047

(22) Filed: Apr. 2, 2013

Related U.S. Application Data
(63) Continuation-in-part of application No. 12/800,554, filed on May 17, 2010.
(60) Provisional application No. 61/619,388, filed on Apr. 2, 2012.
(60) Provisional application No. 61/216,306, filed on May 15, 2009.

(51) Int. Cl. H01S 5/20; B23K 26/36

(52) U.S. Cl. CPC H01S 5/20; B23K 26/367
USPC 219/121.69; 372/45.01; 438/29; 219/121.68

(57) ABSTRACT

A system for narrowing the spectral output of diode lasers through the use of dielectric stacks in the laser cavity comprising an alternating sequence of layers of dielectric material and air, which dielectric stacks are fabricated through the controlled laser ablation of the dielectric material.

### CROSS-REFERENCE TO RELATED APPLICATIONS

The present application claims the benefit of U.S. Provisional Patent Application No. 61/619,388 filed on Apr. 2, 2012, and is a continuation-in-part of U.S. patent application Ser. No. 12/800,554 filed on May 17, 2010, which claims the benefit of U.S. Provisional Patent Application No. 61/216,306 filed on May 15, 2009, all of which are incorporated herein by reference.

### TECHNICAL FIELD OF THE INVENTION

The present invention relates to a method and apparatus for the line narrowing of a diode laser. More specifically, it relates to a method and apparatus for the line narrowing of a diode laser with an integrated Bragg reflector fabricated using controlled laser ablation.

### BACKGROUND OF THE INVENTION

Diode lasers notionally operate in the 800 nm range with a ˜2 nm wide spectral output. Many applications such as diode pumped alkali lasers (“DPALs”) require spectral outputs of diode lasers to be reduced to the ˜0.5 nm range or less.

The current approach to narrowing the spectrum (“line narrowing”) of a diode laser is to couple the laser output into an external optical cavity that utilizes a Volumetric Bragg Reflector. See, e.g., Glebov, et al., “New Approach to Robust Optics for HEL Systems,” Proceedings of SPIE Vol. 4724 (2002). A Volumetric Bragg, Reflector (also called a Distributed Bragg reflector, or a Volumetric Bragg Grating (collectively, a “VBG”)) is a structure which consists of a dielectric material with periodic changes in the index of refraction. With traditional materials, the emission and the reflectivity are dependent on temperature since thermal expansion of the substrate changes the spacing of the grating planes. As shown in FIG. 1, this approach also adds considerable size to each diode laser bar, and as a result becomes a major constraint of a high power diode laser system.

The present invention uses an integrated Bragg reflector comprising two dielectric stacks with each stack comprising an alternating sequence of layers of dielectric substrate and air in the diode laser cavity to achieve line narrowing, which greatly reduces the temperature dependence and the overall size of the system. The integrated Bragg reflector is fabricated using controlled laser ablation of the dielectric substrate.

### SUMMARY

The present invention is a method and apparatus for the line narrowing of diode lasers. The spectral output of the laser is narrowed by using two dielectric stacks in the laser cavity, each stack comprising an alternating sequence of layers of dielectric substrate and air. The dielectric stacks are fabricated through the use of controlled laser ablation of the dielectric substrate.

These aspects of the invention are not meant to be exclusive and other features, aspects, and advantages of the present invention will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a representation of a Volumetric Bragg Reflector in the prior art

FIG. 2 is a schematic diagram of a preferred embodiment of the present invention.

FIG. 3 is a plot of the optical reflectance of the band edge of a DIBR low structure of a preferred embodiment of the present invention.

FIG. 4 is a plot of the optical reflectance of the band edge of a DIBR high structure of a preferred embodiment of the present invention.

FIG. 5 is a plot of the round trip optical reflectance of a laser cavity of a preferred embodiment of the present invention.

FIG. 6 is a plot of the round trip optical reflectance of a laser cavity of a preferred embodiment of the present invention including a laser gain profile.

FIG. 7 is a merit table for possible dielectric materials for use in a preferred embodiment of the present invention.

FIG. 8 is a schematic diagram of a preferred embodiment of the present invention.

FIG. 9 is a schematic diagram of a preferred embodiment of the present invention.

FIG. 10 is a plot of the absorption coefficients versus the photon energy of photons in quartz.

FIG. 11 is a plot of the absorption coefficients versus the photon energy of photons in ZERODUR®.

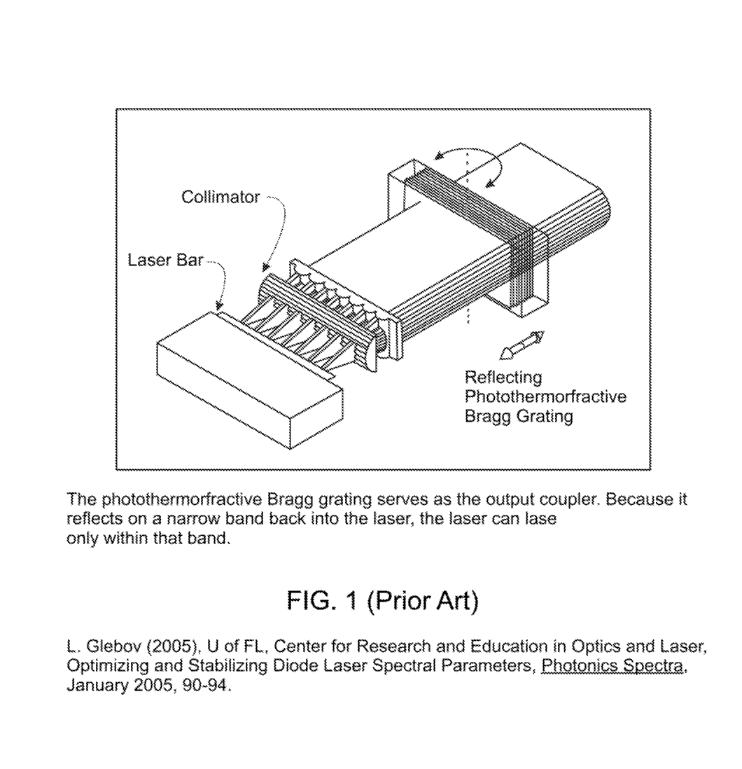

### DETAILED DESCRIPTION OF PREFERRED EMBODIMENTS

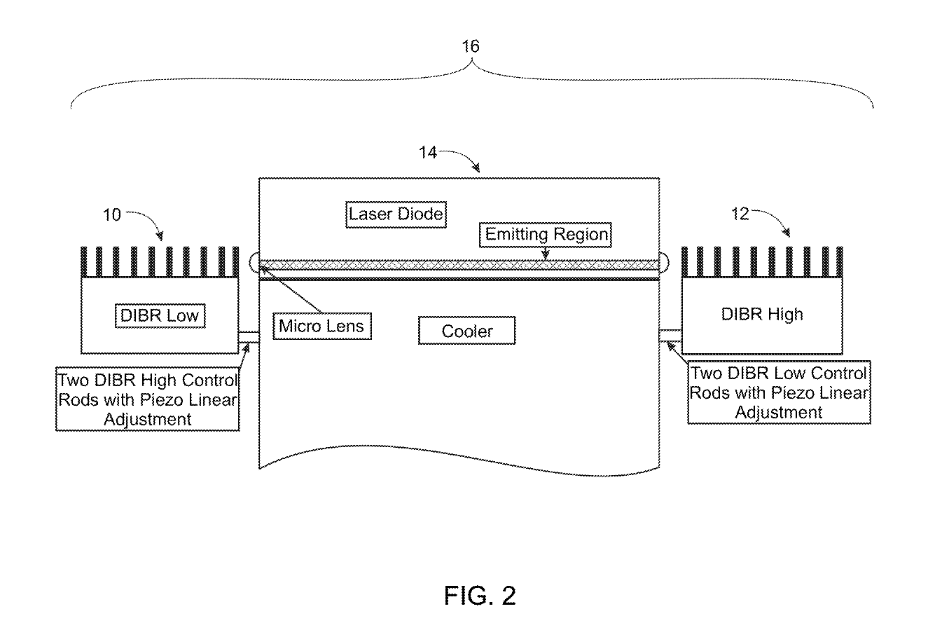

The present invention is a method and apparatus for the line narrowing of diode lasers. As shown in FIG. 2, two dielectric stacks 10, 12 are used together with a diode laser 14 to form a laser cavity 16 with the dielectric stacks at opposite ends of the laser cavity. The upper band edge of the bandpass reflector of one of the dielectric stacks 10 (the “DIBR low structure”) is matched with the lower band edge of the bandpass reflector of the other dielectric stack 12 (the “DIBR high structure”).

The dielectric stacks are comprised of air and a dielectric material with a low coefficient of thermal expansion (“CTE”). The dielectric stacks are fabricated using controlled laser ablation of the dielectric material.

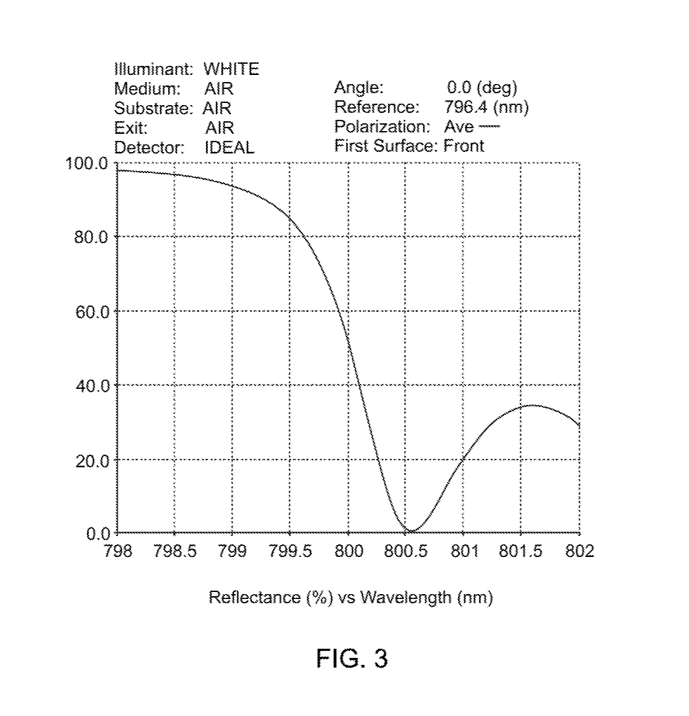

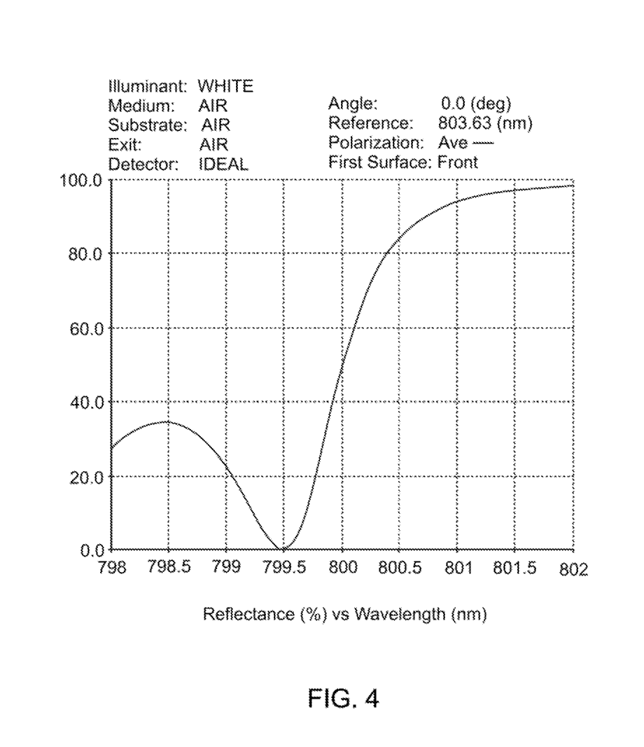

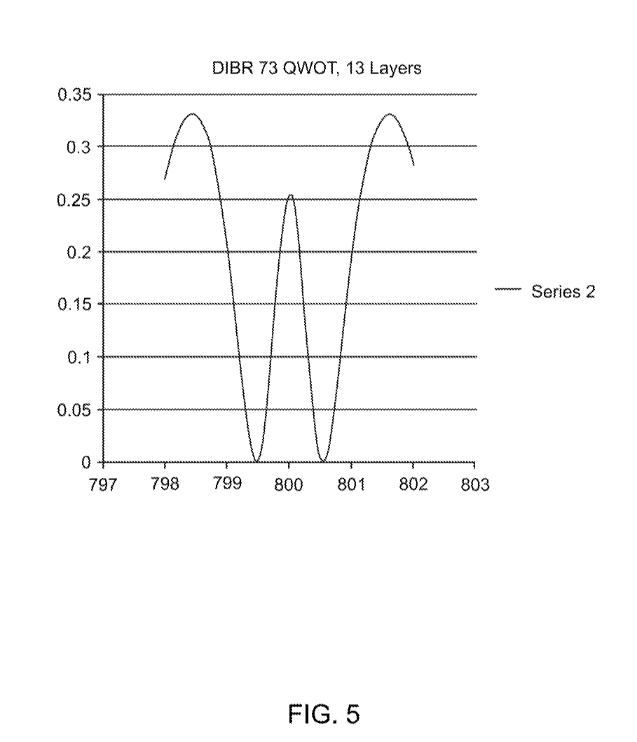

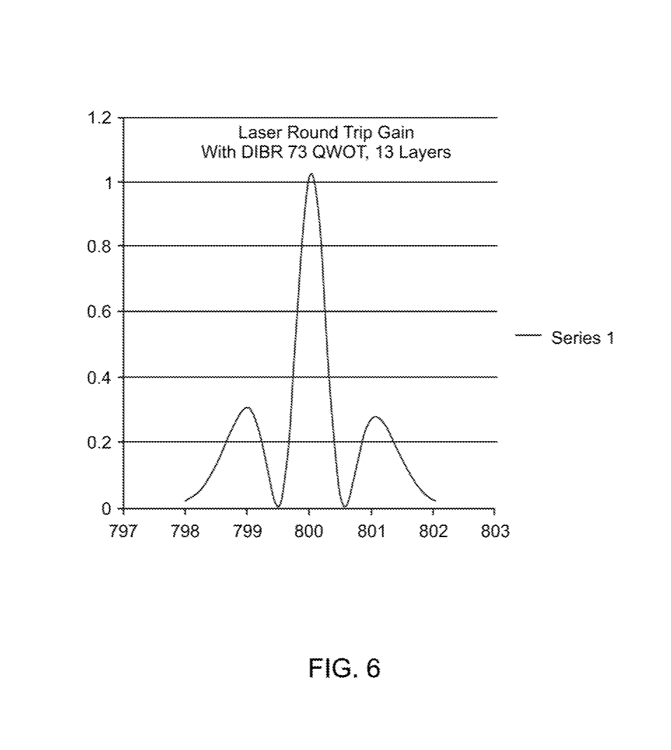

In a preferred embodiment, the dielectric stack combination creates a bandpass reflector at a design center wavelength. The thickness of the materials in the dielectric stack is measured in multiples of the Quarter Wave Optical Thickness (QWOT). The optical reflectance of the hand edge of DIBR low is shown in FIG. 3 and optical reflectance of the band edge of DIBR high is shown in FIG. 4 for an embodiment achieving narrowing at 800 nm. For this embodiment, the DIBR low bandpass reflector was centered at 796.68 nm with its upper edge at 800 nm, and the DIBR high bandpass reflector was centered at 803.63 nm with its lower edge at 800 nm. Radiation inside the cavity impinging upon the DIBR high structure is reflected back into the cavity with characteristics shown m FIG. 4. When this radiation impinges upon the DIBR low structure, it is reflected back into the cavity with characteristics shown in FIG. 3. Thus the round trip optical reflectance of the cavity is the multiple of FIGS. 3 and 4. This is shown in FIG. 5 for the embodiment achieving narrowing at 800 nm. The bandwidth of the cavity alone is 0.56 nm at the design center wavelength of 800 nm. When a laser diode gain profile is included to show the round trip optical gain, the result is shown in FIG. 6, where the bandwidth of the round trip gain is now 0.5 nm at the design center wavelength of 800 nm. The design center wavelength can be changed by simply changing the bandpass centers of the DIBR low and DIBR high dielectric stacks.

Generally laser cavities have reflectors which have reflectances that do not vary over the bandwidth of the laser gain. In the case of conventional laser diode cavities, the cavity mirrors are uniform in reflectance over the ˜2 nm of laser gain profile. In the present invention, the reflectances of the mirrors vary across the laser gain profile. The two mirrors are different because a narrow band (<1 nm bandwidth) mirror cannot be made from a dielectric stack; they are typically 50 nm or greater in bandwidth. With two different mirrors one can use the edge of the reflectance bandwidth of the much broader dielectric stack. FIG. 3 shows the upper wavelength edge of the reflectance band of a dielectric stack which has bandpass of 8 nm. This is much broader than the variation of the dielectric stack. The variation is designed to occur at 800 nm, but it can be adjusted to any wavelength. FIG. 4 shows the lower wavelength edge of the reflectance band of a dielectric stack of similar design which has bandpass of 8 nm but with a different center wavelength such that its lower edge is at 800 nm. This also can be adjusted to any wavelength. Both of these stacks show reflectance drops in the sub nanometer range. It is easier to have rapid variations in reflectance on the edge of the reflectance band than it is to narrow the reflectance band itself.

If a laser diode is at one end of the cavity and the two dielectric stacks are placed at the other end, the reflectance becomes the maximum of either stack. At any wavelength, what the stack with the lower reflectance passes, the other stack with the higher reflectance will catch and reflect. For FIGS. 3 and 4 the result will he a broadband reflector dip at 800 nm.

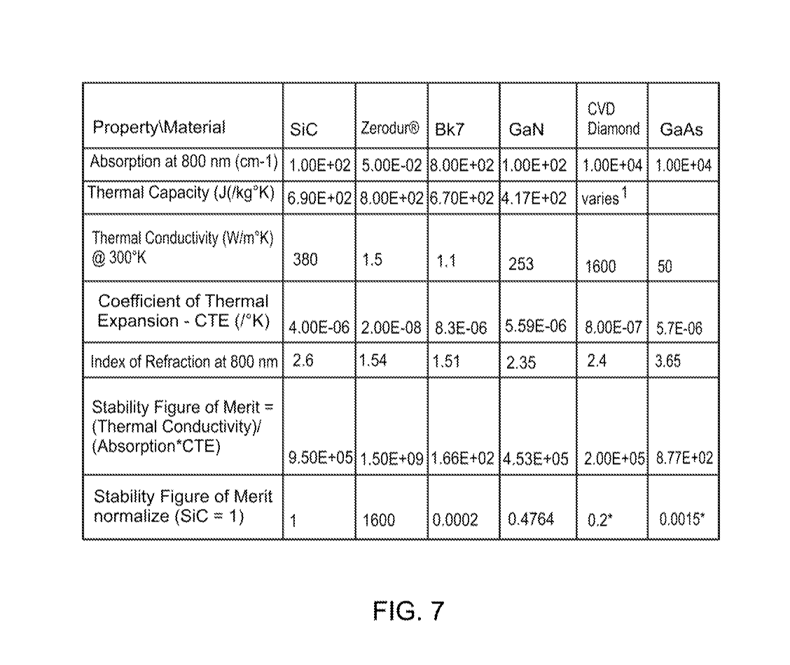

The dielectric stack of the present invention can by fabricated by using controlled laser ablation to create a series of trenches etched across a block of ZERODUR®, or other dielectric materials, including glass materials, that have similar characteristics of low absorption at the laser diode wavelength, low coefficient of thermal expansion (“CTE”), and high thermal conductivity, including without limitation, synthetic glass such as Corning Ultra Low Expansion Glass Code 7972, Sumitomo ZEMAT® ACL 2090, and Clearcan made by Ohara. The merit table shown in FIG. 7 can be used to rank any potential materials with similar characteristics for this application.

In a preferred embodiment, ZERODUR® is chosen based on the analysis in the merit table shown in FIG. 7. ZERODUR® has a CTE of 2 10⁻⁸/° K. The wavelength of the bandpass reflector center changes 10⁻⁵ nm (corresponding to a frequency change of 5 MHz) of the for each 1° K change in temperature.

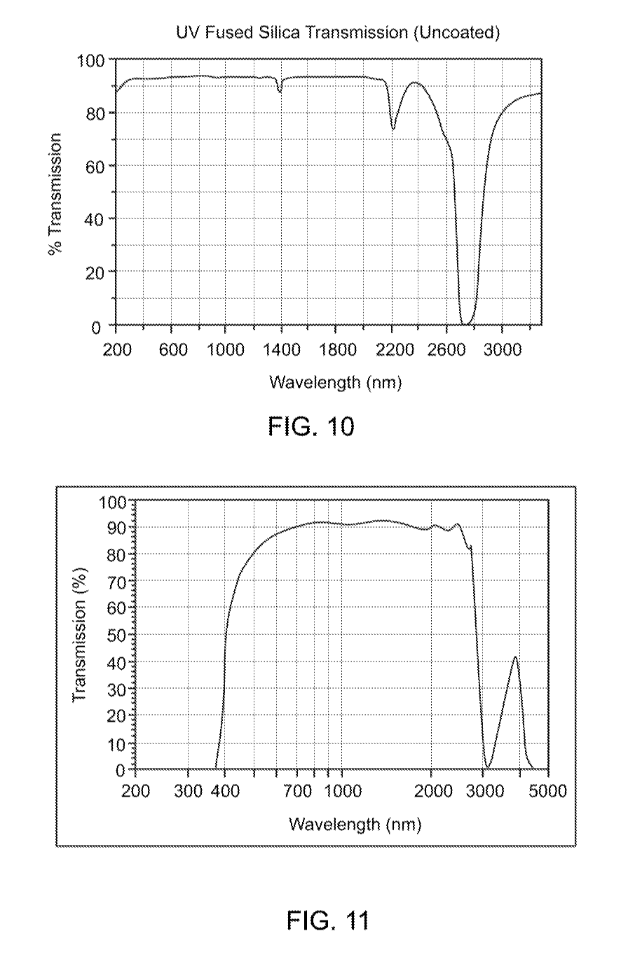

ZERODUR® is a lithium aluminosilicate non-porous glass ceramic. The material is approximately 80% glass materials (55% SiO₂ and 25% Al₂O₃) with several metal oxides added to neutralize thermal expansion and achieve a low Coefficient of Thermal Expansion (CTE). The added dopants are approximately 7% P₂O₅, 3.7% LiO, 2.3% TiO₂, 1.8% ZrO₂, 1.6% ZnO, 1.0% MgO, 0.6% AsO₃, and 0.2% Na₂O. Al₂O₃ does not absorb across its band gap until wavelengths are less than 220 nm as shown in FIG. 10. SiO₂ does not absorb across its band gap until wavelengths are less than 200 nm as shown in FIG. 11. In FIG. 11, it can be seen that at wavelengths less than 380 nm that ZERODUR® is virtually opaque with impurities from the metal oxide dopants. This means that the absorption depth is within a few molecular structures ˜10 nm.

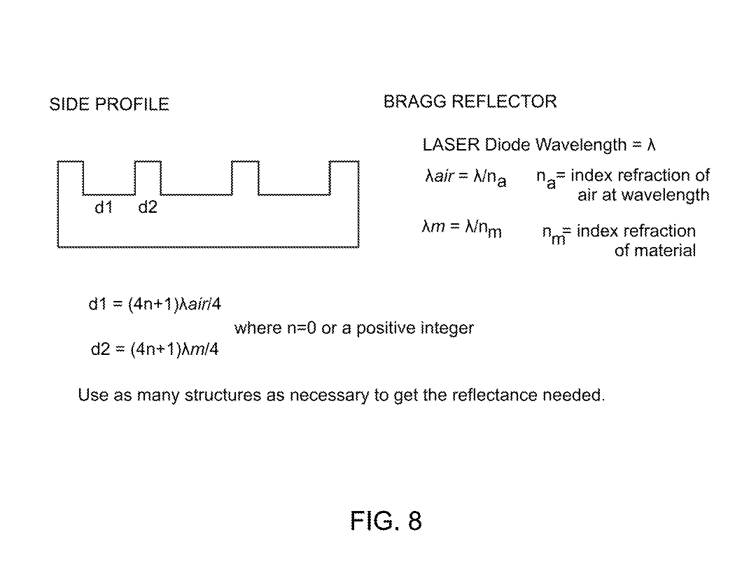

As shown in FIG. 8, to form the dielectric stacks of the present invention, trenches are fabricated in the dielectric material that are (4n+1)λ/4 wide where n is 0 or a positive integer and λ is wavelength of laser diode. Material between trenches is (4n+1)λₘ/4 where n is 0 or a positive integer and λ is wavelength of the laser diode. The air spacing in the dielectric stacks can be λ_{D}/4+n λ_{D} where n is 0 or a positive integer and λ_{D} is the bandpass reflector center wavelength. As n increases, the removal process becomes simpler as contrasted with material deposition processes. Thus the number and thicknesses of the layers can be chosen to optimize the band edge performance and to separate the wavelength reflectance spikes which, in turn, improve the optical bandwidth of the cavity. In a preferred embodiment, the number of QWOTs is 73, thus n=18. Larger values of n moved the spikes too close together, and smaller values of n broadened the optical bandwidth. Furthermore, a value of n=18 places the air gap in the 15,000 nm range which simplifies the design of the optical ablation tool.

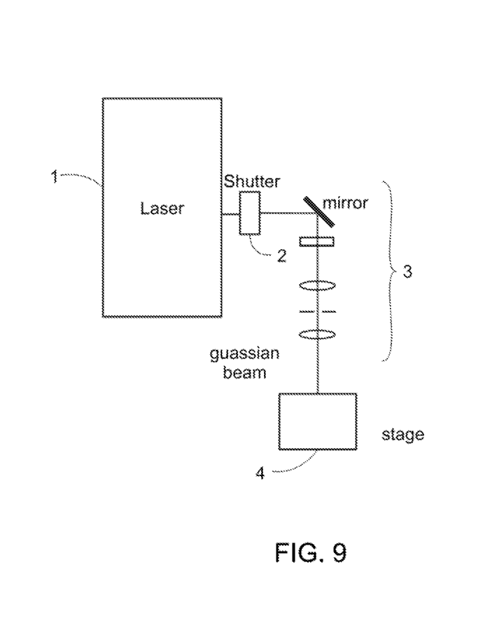

A preferred embodiment of the present invention is a method and apparatus to utilize lasers with short pulse widths at short wavelengths to produce controlled ablation of material. It should be noted that the term laser as used herein includes frequency shifted laser systems. As shown in FIG. 9, a preferred embodiment of the present invention uses a frequency tripled Yb:KYW (ytterbium ions in a lattice of potassium yttrium tungstate) laser 01 as the means for producing 100 fs pulses at a wavelength of 349 nm. It also includes a shutter 02 and an arrangement of one or more mirrors and lens 03, known to those skilled in the art, to focus a Gaussian beam or an appropriately structured beam on a block of ZERODUR® 04. Also, other means known to those skilled in the art may be used to produce laser pulses with short pulse widths at short wavelengths.

At wavelengths of 359 or 262 nm electrons are excited from the valence band to a very high energy state in the conduction band of many of the metal oxide dopants within a 10 nm (100 A) absorption depth as shown in FIG. 11. These highly placed electrons can be photoionized (excited to a free ion state) by absorbing another photon (1 free electron for 2 photons) or can exchange energy with a valence band electron to end up with two lower energy conduction band electrons, each of which can be photoionized in a single step (3 free electrons for 2 photons).

At intensities less than ˜10¹¹ W/cm² the excited electron density grows to the critical density for 355 nm plasma frequency, nₑ ˜8.9 10²¹/cm³ or if 262 nm lasers are used, 1.6 10²²/cm³. Absorption then proceeds by a classic free carrier absorption model, but the absorption depth is now determined by the material parameters. It is estimated that the main burst of energy will be absorbed in ˜8 nm with an energy absorption of 10-30 kJ/cm³. At this point, the energetic electrons leave the ZERODUR® or other dielectric material and a Coulombic explosion follows. In other words, when electrons become energetic enough, they will leave the material surface leaving behind positively charged ions that then fly apart due to electrostatic forces. This creates a shock that blows away the material without any melting.

The ablation process is initiated through an absorption process to the hand gap of the material with a second photon to create the free electron to start plasma heating with subsequent Coulombic explosion. In this case with the dopants present, the initial absorption and free electron creation occur on the dopants. The material is then heated through the classic free electron absorption in the plasma which is comprised of the dopants and the material. The dopants act as an “ablation accelerant”.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention.

What is claimed is:

1. A method for line narrowing a diode laser comprising using a dielectric stack with an edge of a reflectance band for achieving reflectance variations over a gain profile of the laser diode.

2. An apparatus for line narrowing a diode laser comprising,
a diode laser cavity;
a first dielectric stack and a second dielectric stack at opposite ends of the laser cavity with the diode laser between them;
the first dielectric stack and the second dielectric stack each comprising an alternating sequence of layers of a dielectric material and air;
the first dielectric stack having a bandpass reflector with an upper band edge; and
the second dielectric stack having a bandpass reflector with a lower band edge such that the upper band edge of the first dielectric stack matches the lower band edge of the second dielectric stack.

3. The approach of claim 1 wherein the dielectric material is ZERODUR®.

4. A method for line narrowing of diode lasers comprising,
fabricating a first dielectric stack and a second dielectric stack each comprising an alternating sequence of layers of a dielectric material and air;
matching an upper band edge of bandpass reflector of the first dielectric stack with a lower band edge of a bandpass reflector of the second dielectric stack; and
creating a laser cavity with the first dielectric stack and the second dielectric stack at opposite ends of the laser cavity with the diode laser between them.

5. The method of claim 4 wherein the dielectric material is synthetic glass.

6. An apparatus for controlled laser ablation of dielectric material comprising,
a means to apply laser pulses in pulse widths of 500 fs or shorter at wavelengths of 360 nm or shorter to the dielectric stack, and
a lens to apply the laser pulses, wherein the intensity of each pulse is 10¹¹ W/cm² or less and each pulse produces a laser ablation depth of about 30 nm or less.

7. The apparatus of controlled laser ablation of claim 6 wherein the dielectric material is ZERODUR®.

8. A method for controlled laser ablation of dielectric material with a dopant comprising,
applying a first photon to the dielectric material with a dopant to excite an electron to move from the valence band to the conduction band of the dopant;
applying a second photon to the dielectric material to excite the electron from the conduction band of the dopant to a free state, wherein the first and second photons are generated using a single laser pulse in pulse widths of 500 fs or shorter at wavelengths of 360 nm or shorter, wherein each of the laser pulses has an intensity of 10¹¹ W/cm² or less; and
producing a laser ablation depth in the dielectric material of about 30 nm or less per laser pulse.

9. The method for controlled laser ablation of claim 8, wherein the dielectric material is synthetic glass.
